(19) United States
(12) Patent Application Publication
(10) Pub. No.: US 2024/0349507 A1
(43) Pub. Date: Oct. 17, 2024

(54) SEMICONDUCTOR DEVICE AND MANUFACTURING METHOD OF A SEMICONDUCTOR DEVICE

(71) Applicant: SK hynix Inc., Icheon-si (KR)

(72) Inventor: Nam Jae LEE, Icheon-si (KR)

(73) Assignee: SK hynix Inc., Icheon-si (KR)

(21) Appl. No.: 18/362,688

(22) Filed: Jul. 31, 2023

(30) Foreign Application Priority Data
Apr. 17, 2023 (KR) 10-2023-0049815

(51) Int. Cl. H10B 43/35; H01L 23/00; H01L 25/00; H01L 25/065; H01L 25/18; H10B 41/27; H10B 41/35; H10B 43/27; H10B 80/00

(52) U.S. Cl. CPC H10B 43/35; H01L 24/08; H01L 24/80; H01L 25/0657; H01L 25/18; H01L 25/50; H10B 41/27; H10B 41/35; H10B 43/27; H10B 80/00; H01L 2224/08145; H01L 2224/80895; H01L 2224/80896; H01L 2924/1431; H01L 2924/14511

(57) ABSTRACT

A semiconductor device includes a gate structure located between a bit line and a source structure, the gate structure including stacked word lines. The semiconductor device also includes a select line structure located between the gate structure and the source structure, the select line structure including an epitaxial pattern and a silicide layer. The semiconductor device further includes a channel structure extending through the gate structure and the select line structure, the channel structure connected between the source structure and the bit line.

### CROSS-REFERENCE TO RELATED APPLICATION

This application claims priority under 35 U.S.C. § 119(a) to Korean Patent Application No. 10-2023-0049815 filed on Apr. 17, 2023, in the Korean Intellectual Property Office, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, to improve the operational reliability of such a semiconductor device, various structures and manufacturing methods have been developed.

### SUMMARY

In an embodiment, a semiconductor device may include: a gate structure located between a bit line and a source structure, the gate structure including stacked word lines; a select line structure located between the gate structure and the source structure, the select line structure including an epitaxial pattern and a silicide layer; and a channel structure extending through the gate structure and the select line structure, the channel structure connected between the source structure and the bit line.

In an embodiment, a semiconductor device may include: a first wafer including a gate structure including drain select lines and word lines, source select lines including an epitaxial pattern and a silicide layer, and a first bonding pad; and a second wafer including a peripheral circuit and a second bonding pad and electrically connected to the first wafer through the first bonding pad and the second bonding pad.

In an embodiment, a manufacturing method of a semiconductor device may include: forming a stack on a substrate, the substrate including an epitaxial layer on a front surface of the substrate; forming a channel structure extending into the substrate through the stack and the epitaxial layer; removing a rear surface of the substrate to expose the epitaxial layer; and forming a select line structure by siliciding the epitaxial layer.

In an embodiment, a manufacturing method of a semiconductor device may include: forming a first silicide layer on a substrate, the substrate including an epitaxial layer on a front surface of the substrate; forming a stack on the first silicide layer; forming a channel structure extending into the substrate through the stack, the first silicide layer, and the epitaxial layer; removing a rear surface of the substrate to expose the epitaxial layer; and forming a source structure on the epitaxial layer.

### BRIEF DESCRIPTION OF THE DRAWINGS

FIGS. 1A to 1C are diagrams illustrating the structure of a semiconductor device in accordance with an embodiment.

FIG. 2 is a diagram illustrating the structure of a semiconductor device in accordance with an embodiment.

FIG. 3 is a diagram illustrating the structure of a semiconductor device in accordance with an embodiment.

FIGS. 4A to 4I are diagrams for describing a manufacturing method of a semiconductor device in accordance with an embodiment.

FIGS. 5A to 5C are diagrams for describing a manufacturing method of a semiconductor device in accordance with an embodiment.

FIGS. 6A to 6C are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

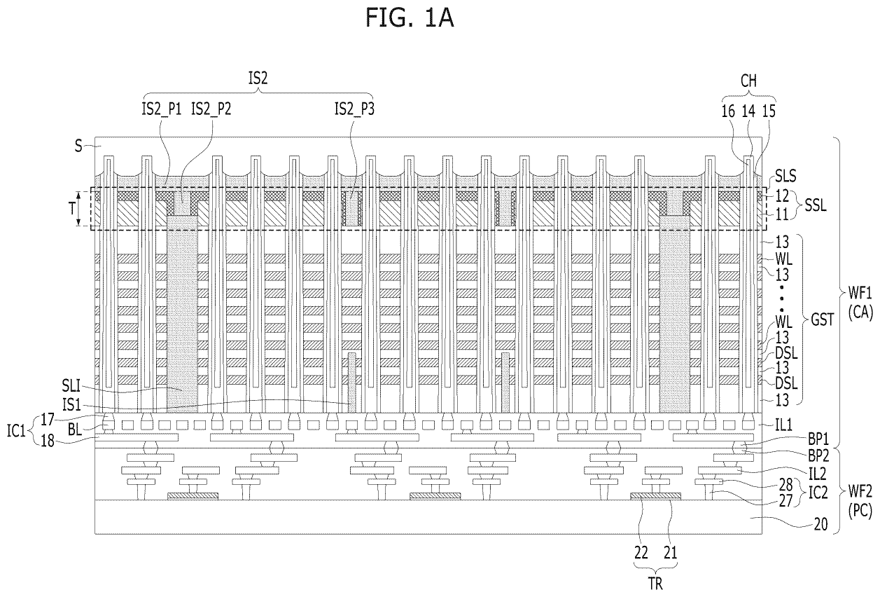

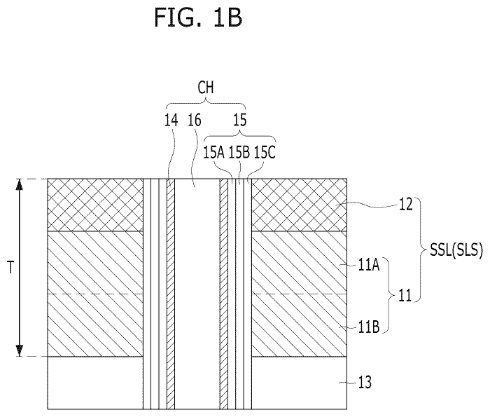

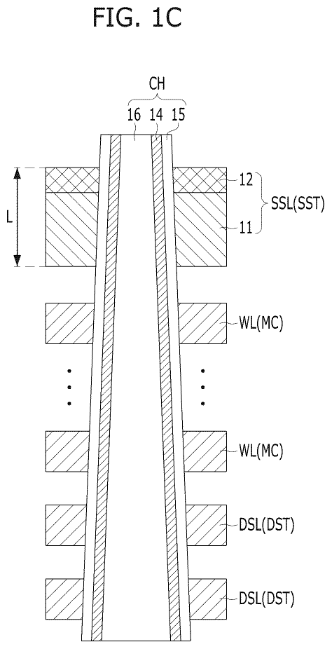

FIGS. 1A to 1C are diagrams illustrating the structure of a semiconductor device in accordance with an embodiment.

Referring to FIG. 1A, the semiconductor device may include a first wafer WF1 and a second wafer WF2. The semiconductor device may have a structure in which the first wafer WF1 and the second wafer WF2 are bonded to each other. The first wafer WF1 and the second wafer WF2 may be electrically connected to each other through a bonding structure. The bonding structure may include a first bonding pad BP1 and a second bonding pad BP2. The second bonding pad BP2 may be electrically connected to the first bonding pad BP1.

The first wafer WF1 may include a cell array CA. The cell array CA may include stacked memory cells. As an example, the cell array CA may include memory strings connected between a source structure S and a bit line BL. The second wafer WF2 may include a peripheral circuit PC. The peripheral circuit PC may include a circuit for driving the cell array CA. As an example, the peripheral circuit PC may include a page buffer, a row decoder, and the like. The peripheral circuit and the cell array CA may be bonded to each other through the bonding structure.

At least one of the first wafer WF1 and the second wafer WF2 might not include a substrate. As an example, after bonding the first wafer WF1 and the second wafer WF2, a substrate of the first wafer WF1 may be removed. The first wafer WF1 might not include the substrate. The substrate may be completely removed or a partially removed from the first wafer WF1. A substrate of at least one of the first wafer WF1 and the second wafer WF2 may be formed after the bonding of the first wafer WF1 and the second wafer WF2. As an example, a select line structure SLS, a source structure S, a metal layer, etc. may serve as the substrate.

The semiconductor device may include a gate structure GST, a select line structure SLS, and a channel structure CH. The semiconductor device may further include at least one of a slit structure SLI, a first isolation structure IS1, a second isolation structure IS2, a source structure S, a first interconnection structure IC1, a first bonding pad BP1, a substrate 20, a transistor TR, a second interconnection structure IC2, and a second bonding pad BP2. The gate structure GST, the select line structure SLS, the channel structure CH, the slit structure SLI, the first isolation structure IS1, the second isolation structure IS2, the source structure S, the first interconnection structure IC1, and the first bonding pad BP1 may belong to the first wafer WF1. The substrate 20, the transistor TR, the second interconnection structure IC2, and the second bonding pad BP2 may belong to the second wafer WF2.

The gate structure GST may include conductive layers and insulating layers 13 that are alternately stacked. The conductive layers may be gate lines such as word lines WL and drain select lines DSL. As an example, the gate structure GST may include the drain select lines DSL and the word lines WL stacked on the drain select lines DSL.

The source structure S may be located on the gate structure GST. The source structure S may include a conductive material such as polysilicon, tungsten (W), or molybdenum (Mo). The source structure S may have a structure of a single layer or a multilayer.

The select line structure SLS may be located between the gate structure GST and the source structure S. The select line structure SLS may include at least one epitaxial pattern 11 and at least one silicide layer 12. The select line structure SLS may include a plurality of select lines, and the select lines may be source select lines SSL, drain select lines DSL, and the like. As an example, each of the source select lines SSL may include the epitaxial pattern 11 and the silicide layer 12.

The epitaxial pattern 11 may be located on the gate structure GST, and the silicide layer 12 may be located on the epitaxial pattern 11. The silicide layer 12 may surround an upper surface and sidewalls of the epitaxial pattern 11. The silicide layer 12 may include a metal such as nickel (Ni), titanium (Ti), or platinum (Pt). As an example, the silicide layer 12 may include nickel silicide. Referring to FIG. 1B, the epitaxial pattern 11 may include a first epitaxial pattern 11A and a second epitaxial pattern 11B. The first epitaxial pattern 11A and the second epitaxial pattern 11B may have different impurity doping concentrations. As an example, the first epitaxial pattern 11A may be an undoped silicon layer, and the second epitaxial pattern 11B may be a doped silicon layer. The second epitaxial pattern 11B may include at least one of phosphorus (P) and boron (B). Because the select line structure SLS is formed separately from the gate structure GST, a thickness T of the select line structure SLS may be adjusted according to the characteristics of a select transistor. Resistivity may be reduced by putting a silicide material and a dopant into the select line structure SLS.

The slit structure SLI may extend into the select line structure SLS through the gate structure GST. The slit structure SLI may be located at a boundary between memory blocks. The memory block may be a unit of an erase operation. The first isolation structure IS1 may be located in the gate structure GST and may extend between the drain select lines DSL. The second isolation structure IS2 may be located between the select line structure SLS and the source structure S, and may extend between the source select lines SSL. The second isolation structure IS2 may include a first part IS2_P1, a second part IS2_P2, and a third part IS2_P3. The first part IS2_P1 may be located on the select line structure SLS. An upper surface of the first part IS2_P1 may be flat or have irregularities. An upper surface of the first part IS2_P1 may contact a lower surface of the source structure S. The lower surface of the source structure S may be flat or have irregularities. At least one of the select line structure SLS, the second isolation structure IS2 and the source structure S may serve as the substrate of the first wafer WF1.

The second part IS2_P2 may protrude from the first part IS2_P1 and may extend into the select line structure SLS. The second part IS2_P2 may be located to correspond to the slit structure SLI. The second part IS2_P2 may extend between the source select lines SSL and may be connected to the slit structure SLI. The silicide layer 12 may be located between the upper surface of the epitaxial pattern 11 and the first part IS2_P1, and may extend between the sidewall of the epitaxial pattern 11 and the second part IS2_P2.

The third part IS2_P3 may protrude from the first part IS2_P1 and may extend into the select line structure SLS. The third part IS2_P3 may be located to correspond to the first isolation structure IS1. The third part IS2_P3 may be located to face to the first isolation structure IS1 with the word lines WL interposed therebetween. The third part IS2_P3 may extend between the source select lines SSL and may extend into the gate structure GST.

The second part IS2_P2 and the third part IS2_P3 may have substantially the same height or different heights. The second part IS2_P2 may partially pass through the epitaxial pattern 11, and a bottom surface of the second part IS2_P2 may be located between the upper and lower surfaces of the epitaxial pattern 11. The third part IS2_P3 may pass through the epitaxial pattern 11 and extend into the gate structure GST. The silicide layer 12 may be located between the upper surface of the epitaxial pattern 11 and the first part IS2_P1, and may extend between the sidewall of the epitaxial pattern 11 and the third part IS2_P3.

The channel structure CH may extend through the gate structure GST and the select line structure SLS. The channel structure CH may extend into the source structure S through the second isolation structure IS2. The channel structure CH may include a channel layer 14. The channel layer 14 may protrude from an upper surface of the second isolation structure IS2. The channel layer 14 may be directly connected to the source structure S or may be connected to the source structure S through the epitaxial pattern.

The channel structure CH may further include at least one of a memory layer 15 and an insulating core 16. The memory layer 15 may surround sidewalls of the channel layer 14, and may extend through the gate structure GST, the select line structure SLS, and the second isolation structure IS2. The memory layer 15 may expose an end of the channel layer 14, and the end of the channel layer 14 may be connected to the source structure S. Referring to FIG. 1B, the memory layer 15 may include at least one of a tunneling layer 15A, a data storage layer 15B, and a blocking layer 15C. As an example, the data storage layer 15B may include a floating gate, polysilicon, a charge trap material, nitride, a variable resistance material, or the like.

The memory strings may be arranged along the channel structure CH. Referring to FIG. 1C, a drain select transistor DST may be located in a region where the channel structure CH and the drain select line DSL intersect each other. A memory cell MC may be located in a region where the channel structure CH and the word line WL intersect each other. A source select transistor SST may be located in a region where the channel structure CH and the source select line SSL intersect each other. At least one source select transistor SST, memory cells MC, and at least one drain select transistor DST sharing the channel layer 14 may constitute a memory string.

The memory cell MC and the drain select transistor DST may be located in the gate structure GST. Because the source select line SSL is formed as a separate structure from the gate structure GST, the source select transistor SST may be located outside the gate structure GST. The source select line SSL may include the epitaxial pattern 11 and the silicide layer 12.

A channel of the source select transistor SST may be formed in a portion of the channel layer 14 where the source select line SSL and the channel structure CH overlap each other, and a channel length L of the source select transistor SST may be determined according to a thickness T of the source select line SSL. When an erase operation is performed using a gate induced drain leakage (GIDL) current, the amount of GIDL current that is generated may vary depending on the channel length L. The amount of GIDL current that is generated by a source select transistor SST having a large channel length L may be greater than the amount of GIDL current generated by a source select transistor SST having a small channel length L.

When the source select transistor SST is included in the gate structure GST, there may be a limit to increasing the channel length L. Alternatively, the source select line SSL is formed separately from the gate structure GST, so that the source select line SSL may be formed to have a sufficient channel length L. Accordingly, instead of increasing the number of source select transistors SST included in the memory string, the amount of GIDL current may be secured by increasing the channel length L.

The first interconnection structure IC1 may be located under the gate structure GST. The first interconnection structure IC1 may be located in a first interlayer dielectric layer IL1. The first interconnection structure IC1 may provide a path for transmitting a bias to the cell array CA. The first interconnection structure IC1 may be electrically connected to the cell array CA. As an example, the first interconnection structure IC1 may be electrically connected to the at least one of the gate structure GST, channel structure CH, select line structure SLS and the source structure S. The first bonding pad BP1 may be electrically connected to the cell array CA through the first interconnection structure IC1. The first interconnection structure IC1 may include a contact plug 17, a wire line 18, and the like. As an example, the first interconnection structure IC1 may include the bit line BL. The gate structure GST may be located between the bit line BL and the source structure S. The channel structure CH may be connected between the bit line BL and the source structure S.

The peripheral circuit PC may be located on the substrate 20. The peripheral circuit PC may include the transistor TR, and the transistor TR may include a gate insulating layer 21 and a gate electrode 22. A second interlayer dielectric layer IL2 may be located on the substrate 20, and the second interconnection structure IC2 may be located in the second interlayer dielectric layer IL2. The second interconnection structure IC2 may be electrically connected to the peripheral circuit PC. The second interconnection structure IC2 may include a contact plug 27, a wire line 28, and the like. The second bonding pad BP2 may be electrically connected to the peripheral circuit PC through the second interconnection structure IC2.

According to the structure described above, the select line structure SLS may be located on the gate structure GST. The select line structure SLS may include a plurality of source select lines SSL. It is possible to improve read disturbance by separating the source select lines SSL from each other by the second isolation structure IS2. The source select lines SSL may each include the silicide layer 12. Accordingly, it is possible to reduce the resistivity of the source select lines SSL, and to improve operating characteristics of the source select transistor.

Because the select line structure SLS is formed separately from the gate structure GST, the thickness T of the select line structure SLS may be determined in consideration of the operating characteristics of the source select transistor SST. The select line structure SLS is formed to have a thicker thickness T than the word line WL and/or the drain select line DSL, so that it is possible to secure the channel length L of the source select transistor SST. Accordingly, it is possible to generate a sufficient amount of GIDL current during an erase operation.

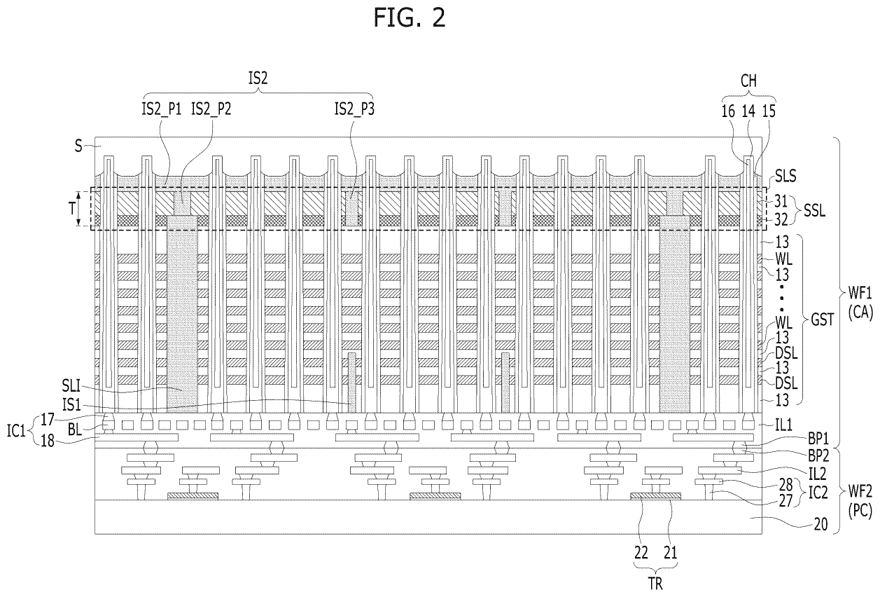

FIG. 2 is a diagram illustrating the structure of a semiconductor device in accordance with an embodiment. Hereinafter, the content overlapping with the previously described content will be omitted.

Referring to FIG. 2, the semiconductor device may include a first wafer WF1 and a second wafer WF2. The first wafer WF1 and the second wafer WF2 may be electrically connected to each other through a first bonding pad BP1 and a second bonding pad BP2. The first bonding pad BP1 may be electrically connected to the first interconnection structure IC1 and the second bonding pad BP2 may be electrically connected to the second interconnection structure IC2. The first wafer WF1 may include a cell array CA. The second wafer WF2 may include a peripheral circuit PC. At least one of the first wafer WF1 and the second wafer WF2 might not include a substrate. At least one of the first wafer WF1 and the second wafer WF2 may include a portion of the substrate or may use a structure such as the source structure S as the substrate.

The semiconductor device may include a gate structure GST, a select line structure SLS, and a channel structure CH. The semiconductor device may further include at least one of a slit structure SLI, a first isolation structure IS1, a second isolation structure IS2, a source structure S, a first interconnection structure IC1, the first bonding pad BP1, a substrate 20, a transistor TR, a second interconnection structure IC2 and the second bonding pad BP2.

The select line structure SLS may include epitaxial patterns 31 and silicide layers 32. The silicide layers 32 may be located on the gate structure GST, and the epitaxial patterns 31 may be respectively located on the silicide layers 32. The silicide layer 32 may include a metal such as nickel (Ni), titanium (Ti), or platinum (Pt). As an example, the silicide layer 32 may include titanium silicide. The epitaxial pattern 31 may include an undoped first epitaxial pattern and a doped second epitaxial pattern.

The slit structure SLI may extend into the silicide layer 32 through the gate structure GST. A first part IS2_P1 of the second isolation structure IS2 may be located on the epitaxial patterns 31. A second part IS2_P2 of the second isolation structure IS2 may extend between the epitaxial patterns 31, and may be connected to the slit structure SLI. A third part IS2_P3 of the second isolation structure IS2 may extend between the epitaxial patterns 31 and the silicide layers 32, and may extend into the gate structure GST.

According to the structure described above, the silicide layer 32 may be located between the gate structure GST and the epitaxial pattern 31. The silicide layer 32 may be used as a source for supplying a photocatalyst in a manufacturing process.

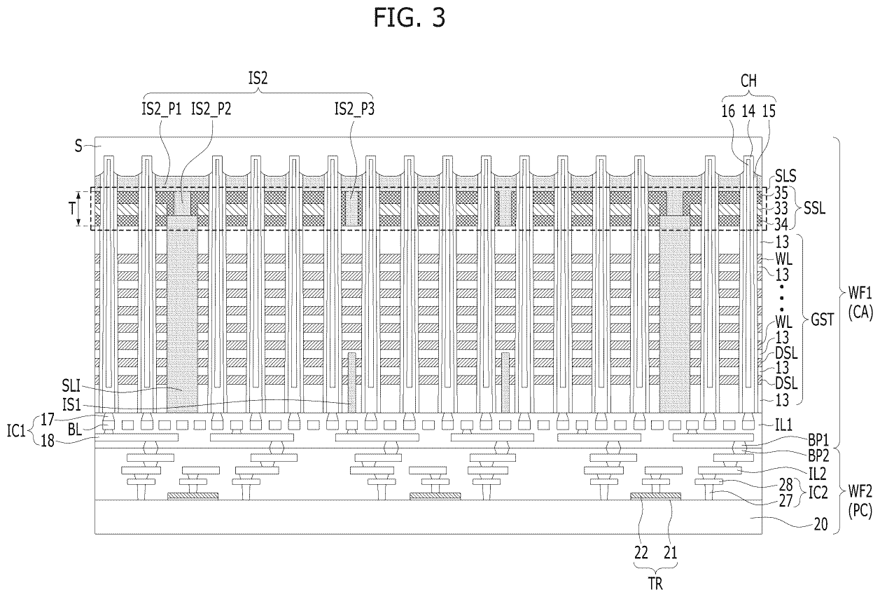

FIG. 3 is a diagram illustrating the structure of a semiconductor device in accordance with an embodiment. Hereinafter, the content overlapping with the previously described content will be omitted.

Referring to FIG. 3, the semiconductor device may include a first wafer WF1 and a second wafer WF2. The first wafer WF1 and the second wafer WF2 may be electrically connected to each other through a first bonding pad BP1 and a second bonding pad BP2. The first wafer WF1 may include a cell array CA. The second wafer WF2 may include a peripheral circuit PC. At least one of the first wafer WF1 and the second wafer WF2 might not include a substrate. At least one of the first wafer WF1 and the second wafer WF2 may include a portion of the substrate or may use a structure such as the source structure S as the substrate.

The semiconductor device may include a gate structure GST, a select line structure SLS, and a channel structure CH. The semiconductor device may further include at least one of a slit structure SLI, a first isolation structure IS1, a second isolation structure IS2, a source structure S, a first interconnection structure IC1, the first bonding pad BP1, a substrate 20, a transistor TR, a second interconnection structure IC2 and the second bonding pad BP2.

The select line structure SLS may include epitaxial patterns 33, first silicide layers 34, and a second silicide layer 35. The first silicide layers 34 may be located on the gate structure GST, and the epitaxial patterns 33 may be located on the first silicide layers 34, respectively. The first silicide layer 34 may include a metal such as nickel (Ni), titanium (Ti), or platinum (Pt). As an example, the first silicide layer 34 may include titanium silicide. The epitaxial pattern 33 may include an undoped first epitaxial pattern and a doped second epitaxial pattern.

The second silicide layer 35 may be located on each of the epitaxial patterns 33. The epitaxial pattern 33 may be located between the first silicide layer 34 and the second silicide layer 35. The second silicide layer 35 may surround an upper surface and sidewalls of the epitaxial pattern 33. The second silicide layer 35 may extend to sidewalls of the first silicide layer 34. The second silicide layer 35 may include a metal such as nickel (Ni), titanium (Ti), or platinum (Pt). As an example, the second silicide layer 35 may include nickel silicide.

The slit structure SLI may extend into the first silicide layer 34 through the gate structure GST. Sidewalls of the slit structure SLI may contact the first silicide layer 34, and an upper surface of the slit structure SLI may contact the second silicide layer 35. A first part IS2_P1 of the second isolation structure IS2 may be located on the second silicide layer 35. A second part IS2_P2 of the second isolation structure IS2 may extend between the second silicide layers 35, and may be connected to the slit structure SLI. A third part IS2_P3 of the second isolation structure IS2 may extend between the second silicide layers 35, and may extend into the gate structure GST.

According to the structure described above, the select line structure SLS may include the first silicide layer 34, the epitaxial pattern 33, and the second silicide layer 35. The first silicide layer 34 and the second silicide layer 35 may include the same metal or different metals. As an example, the first silicide layer 34 may include titanium silicide, and the second silicide layer 35 may include nickel silicide.

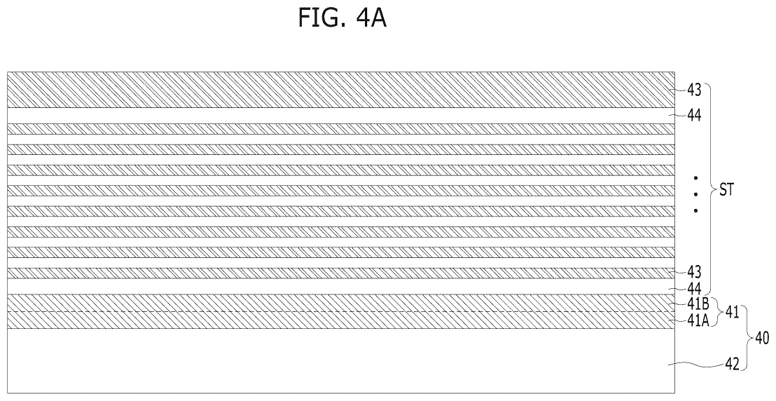

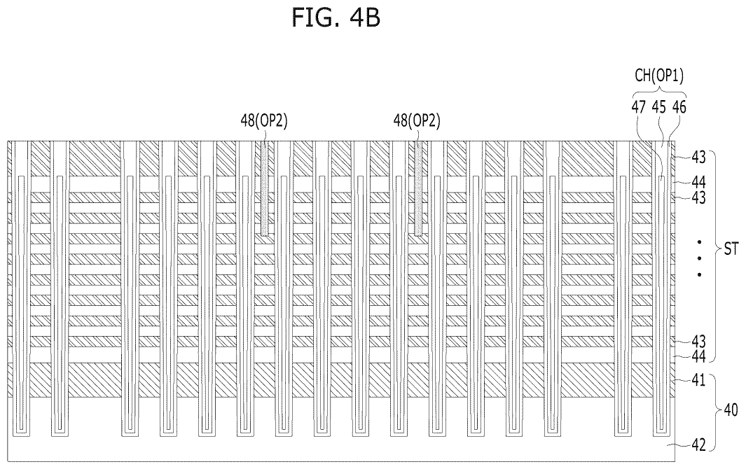

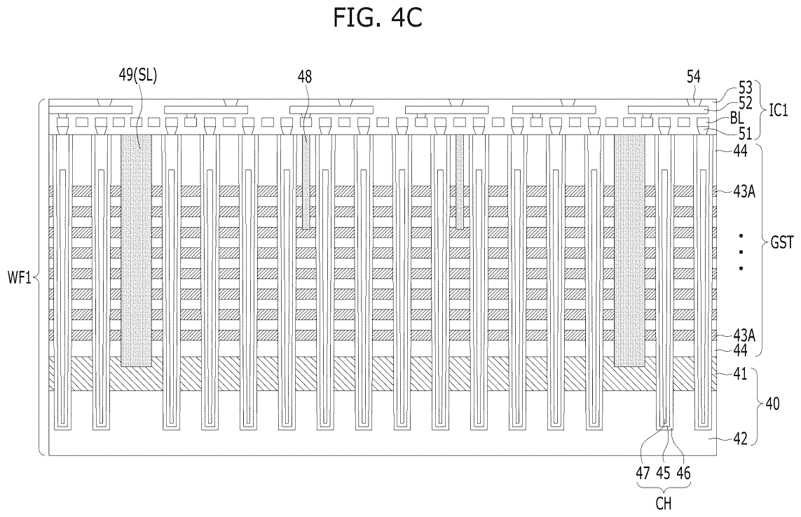

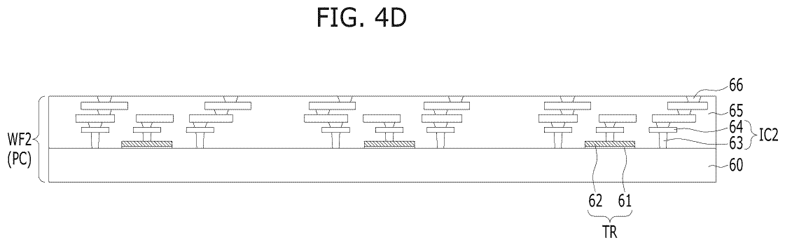

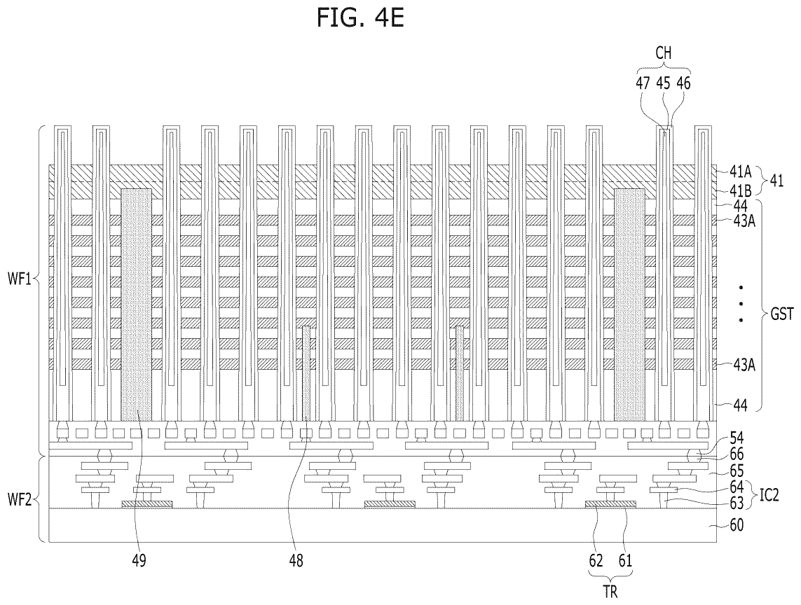

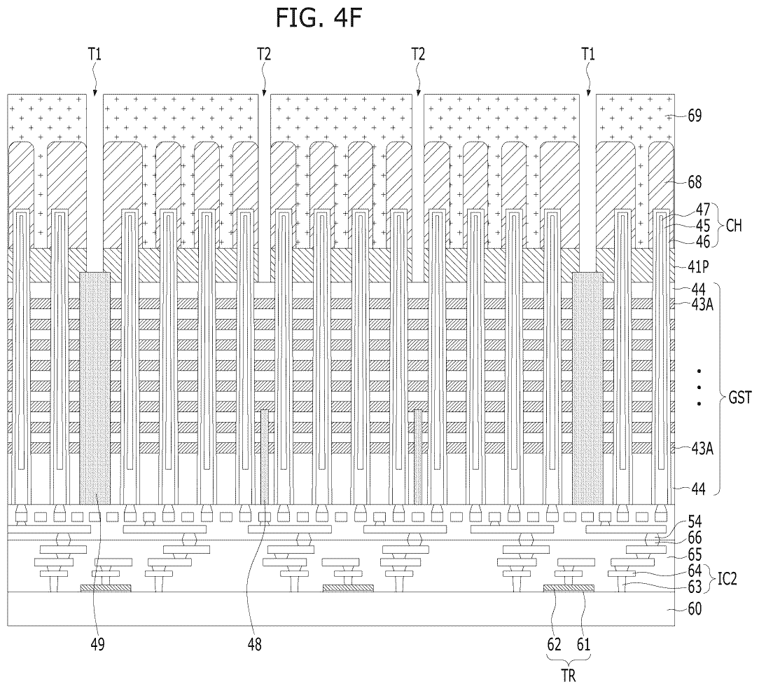

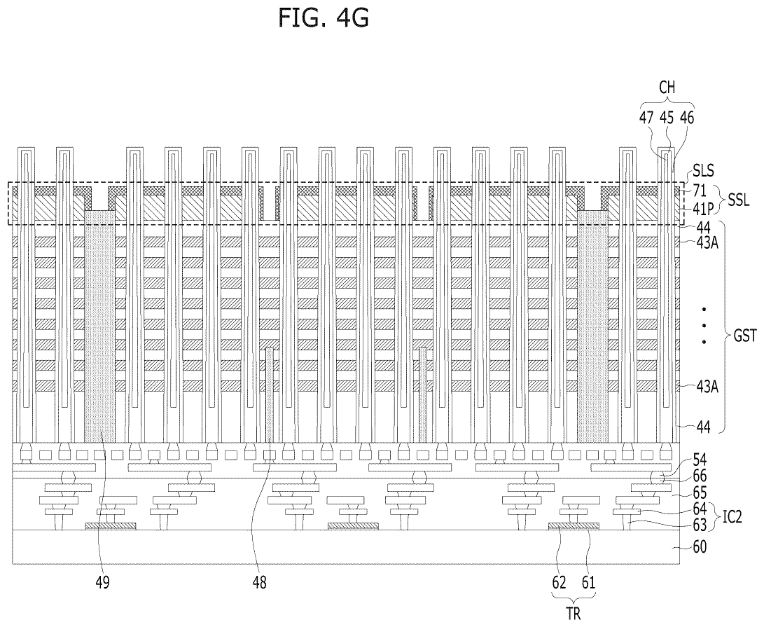

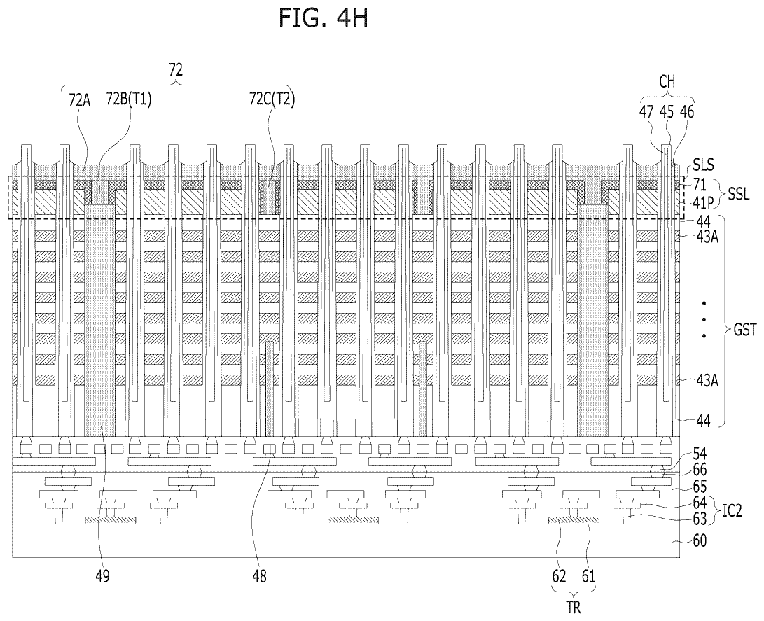

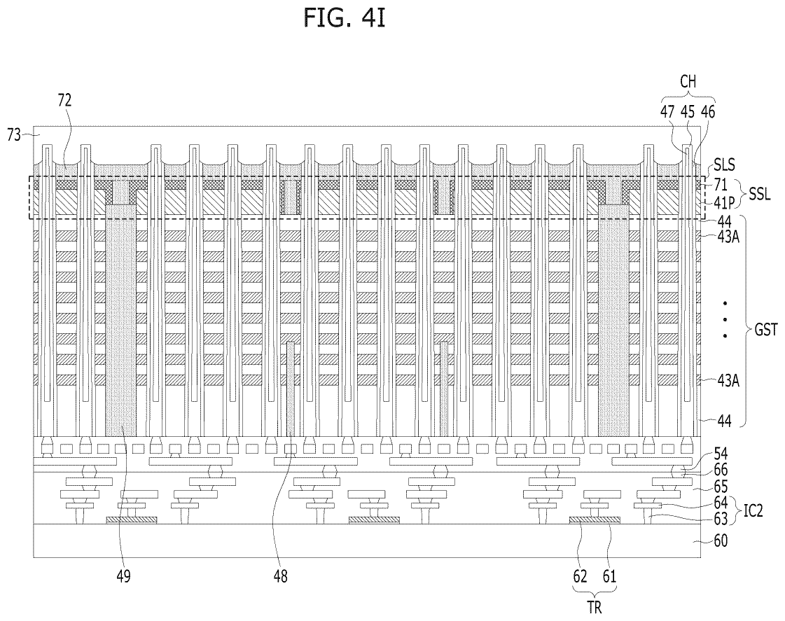

FIGS. 4A to 4I are diagrams for describing a manufacturing method of a semiconductor device in accordance with an embodiment. Hereinafter, the content overlapping with the previously described content will be omitted.

Referring to FIG. 4A, a first substrate 40 may include an epitaxial layer 41 on a front surface thereof. As an example, the first substrate 40 may include a bulk 42 and an epitaxial layer 41. A bulk 42 may be monocrystalline silicon. The epitaxial layer 41 may be a layer grown from the bulk 42 in an epitaxial manner. The epitaxial layer 41 may have a thickness of 1500 angstroms (Å) to 2500 Å.

The epitaxial layer 41 may include a first epitaxial layer 41A and a second epitaxial layer 41B. The first epitaxial layer 41A may be an undoped silicon layer, and the second epitaxial layer 41B may be a doped silicon layer. The second epitaxial layer 41B may include at least one of phosphorus (P) and boron (B).

A stack ST may be formed on the first substrate 40. The stack ST may include first material layers 43 and second material layers 44 that are alternately stacked. The first material layers 43 may each include a material having a high etching selectivity with respect to the second material layers 44. The first material layers 43 may be used to form gate lines, and the second material layers 44 may be used to insulate stacked gate lines from each other. For example, the first material layers 43 may each include a sacrificial material such as nitride, and the second material layers 44 may each include an insulating material such as oxide or nitride. As another example, the first material layers 43 may each include a conductive material such as polysilicon or metal, and the second material layers 44 may each include an insulating material such as oxide or nitride.

The first material layers 43 and the second material layers 44 may have substantially the same thickness or different thicknesses. The uppermost second material layer 44 and/or the lowermost second material layer 44 may have a thicker thickness than the other second material layers 44. The uppermost first material layer 43 may be used as a hard mask in a subsequent process, and may have a thicker thickness than the other first material layers 43.

Referring to FIG. 4B, a channel structure CH may be formed. After a first opening OP1 extending into the first substrate 40 through the stack ST and the epitaxial layer 41 is formed, a memory layer 46, a channel layer 45, and an insulating core 47 may be formed in the first opening OP1. The channel structure CH may extend into the bulk 42 through the epitaxial layer 41.

Subsequently, a first isolation structure 48 may be formed in the stack ST. After a second opening OP2 is formed in the stack ST, the first isolation structure 48 may be formed in the second opening OP2. The second opening OP2 and the first separation structure 48 may be used to separate drain select lines. The first isolation structure 48 may include an insulating material such as oxide, nitride, or air gap.

Subsequently, the uppermost first material layer 43 used as a hard mask may be removed, and an insulating layer may be additionally formed on the stack ST. The additionally formed insulating layer may be used as a part of the stack ST together with the second material layer 44. The stack ST may be patterned in a stepped shape to expose the first material layers 43 included in the stack ST. Alternatively, openings respectively exposing the first material layers 43 may be formed, and contact plugs may be formed in the openings, respectively.

Referring to FIG. 4C, a gate structure GST may be formed. As an example, a slit SL may be formed in the stack ST. The slit SL may extend into the epitaxial layer 41 through the stack ST. Subsequently, the first material layers 43 may be replaced with third material layers 43A through the slit SL. For example, when the first material layers 43 each include a sacrificial material, conductive layers may be formed after the first material layers 43 are removed. As another example, when the first material layers 43 each include a conductive material, a silicidation process may be performed to reduce resistivity of the first material layers 43. Alternatively, the first material layers 43 may be used as the third material layers 43A as they are. Through this, the gate structure GST including the third material layers 43A and the second material layers 44 that are alternately stacked may be formed.

Subsequently, a slit structure 49 may be formed in the slit SL. The slit structure 49 may extend into the epitaxial layer 41 through the gate structure GST. The slit structure 49 may include an insulating material such as oxide, nitride, or air gap. The slit structure 49 may also include a source contact plug and an insulating spacer surrounding sidewalls of the source contact plug.

Subsequently, a first interlayer dielectric layer 53, a first interconnection structure IC1, and a first bonding pad 54 may be formed. The first interconnection structure IC1 may be located in the first interlayer dielectric layer 53. The first interconnection structure IC1 may include a contact plug 51, a wire line 52, and the like. As an example, the first interconnection structure IC1 may include a bit line BL. The first bonding pad 54 may include copper. Thus, the first wafer WF1 including the epitaxial layer 41, the gate structure GST, the channel structure CH, the first interconnection structure IC1, and the first bonding pad 54 may be formed.

Referring to FIG. 4D, a second wafer WF2 including a peripheral circuit PC may be formed. The peripheral circuit PC may include a page buffer, a row decoder, and the like. As an example, a transistor TR including a gate insulating layer 61 and a gate electrode 62 may be formed on a second substrate 60. Subsequently, a second interconnection structure IC2 electrically connected to the peripheral circuit PC may be formed. The second interconnection structure IC2 may be located in the second interlayer dielectric layer 65. The second interconnection structure IC2 may include a contact plug 63, a wire line 64, and the like. Subsequently, second bonding pads 66 may be formed.

Referring to FIG. 4E, the first wafer WF1 and the second wafer WF2 may be bonded to each other. The first wafer WF1 and the second wafer WF2 may be electrically connected to each other by inverting the first wafer WF1 and bonding the first bonding pad 54 and the second bonding pad 66 to each other.

Subsequently, a rear surface of the first substrate 40 may be removed. The epitaxial layer 41 may be exposed by removing the bulk 42 exposed through the rear surface. As an example, the bulk 42 may be removed by grinding, chemical mechanical polishing (CMP), wet etching, or the like. The epitaxial layer 41 may include the undoped first epitaxial layer 41A and the doped second epitaxial layer 41B, and the bulk 42 may have a larger doping concentration than the first epitaxial layer 41A. Accordingly, the epitaxial layer 41 may be exposed by selectively etching the bulk 42. The bulk 42 may be selectively removed without damaging the epitaxial layer 41 by using a difference in impurity concentration between the undoped first epitaxial layer 41A and the bulk 42. Through this, the undoped first epitaxial layer 41A may be exposed. The channel structure CH may also protrude from the undoped first epitaxial layer 41A.

Referring to FIG. 4F, epitaxial patterns 41P may be formed. Mutually separated epitaxial patterns 41P may be formed by forming a first trench T1 and a second trench T2 in the epitaxial layer 41. The first trench T1 may extend between the epitaxial patterns 41P to expose the slit structure 49. The second trench T2 may extend between the epitaxial patterns 41P to expose the gate structure GST. The second trench T2 may be located to correspond to the first isolation structure 48.

As an example, a hard mask 68 may be formed on the epitaxial layer 41. The hard mask 68 may be formed along the profile of the epitaxial layer 41 and the channel structure CH. Subsequently, a mask pattern 69 may be formed on the hard mask 68. The mask pattern 69 may include photoresist. Subsequently, the hard mask 68 may be etched using the mask pattern 69 as an etching barrier, and the epitaxial layer 41 may be etched using the mask pattern 69 and the hard mask 68 as etching barriers to form the epitaxial patterns 41P.

Referring to FIG. 4G, silicide layers 71 may be formed. The silicide layers 71 may be formed by siliciding the epitaxial patterns 41P. Through this, a select line structure SLS including the epitaxial pattern 41P and the silicide layer 71 may be formed. First, the mask pattern 69 and the hard mask 68 may be removed, and a cleaning process may be performed. Subsequently, after a metal layer is formed on the epitaxial patterns 41P, the metal layer and the epitaxial patterns 41P may be reacted through a heat treatment process. The metal layer may include nickel (Ni), platinum (Pt), or the like. Subsequently, an unreacted metal layer may be removed and a cleaning process may be performed. Through this, the surfaces of the epitaxial patterns 41P may be silicided and select lines may be formed. As an example, the select lines may be source select lines (SSL).

Each of the source select lines SSL may include the epitaxial pattern 41P and the silicide layer 71. The silicide layer 71 may surround the epitaxial pattern 41P. As an example, the silicide layer 71 may surround the upper surface and sidewalls of the epitaxial pattern 41P.

Referring to FIG. 4H, a second separation structure 72 may be formed. The second isolation structure 72 may be located on the select line structure SLS, and may extend into the first trench T1 and the second trench T2. The second isolation structure 72 may include a first part 72A located on the select line structure SLS, a second part 72B located in the first trench T1 and a third part 72C located in the second trench T2. An upper surface of the second separation structure 72 may be flat or have irregularities.

As an example, an isolation layer may be formed on the select line structure SLS. The isolation layer may be formed by depositing an insulating material such as oxide. The isolation layer may be formed to cover the channel structure CH. Subsequently, the isolation layer may be etched to form the second isolation structure 72. The isolation layer may be etched using an etch-back process. The separation layer may be selectively etched, and the channel structure CH may protrude from the second separation structure 72. The memory layer 46 may be exposed through an outer wall of the channel structure CH.

Referring to FIG. 4I, the channel layer 45 may be exposed by etching the memory layer 46. The memory layer 46 may be partially etched during the formation of the second separation structure 72 depending on the composition and material of the memory layer 46. As an example, the memory layer 46 may include a tunneling layer surrounding the channel layer 45, a data storage layer surrounding the tunneling layer, and a blocking layer surrounding the data storage layer. The tunneling layer and the blocking layer may each include oxide, and the data storage layer may include nitride. When the isolation layer includes oxide, the blocking layer may be etched and the data storage layer may be exposed when the isolation layer is etched. The data storage layer may be etched using a wet etching process. The tunneling layer may be etched using a dry cleaning process. As a result, the channel layer 45 may be exposed.

Subsequently, a source structure 73 may be formed. As an example, the source structure 73 may be formed by depositing a conductive material such as polysilicon. Subsequently, the source structure 73 may be patterned. As an example, the source structure may be patterned in units of memory blocks.

The source structure 73 may be located on the second isolation structure 72. A lower surface of the source structure 73 may have a shape corresponding to the upper surface of the second separation structure 72. The shape of the upper surface of the second separation structure 72 may be transferred to the lower surface of the source structure 73, and the lower surface of the source structure 73 may be flat or have irregularities.

According to the manufacturing method described above, the select line structure SLS may be formed by siliciding the epitaxial layer 41. Accordingly, it is possible to reduce the resistivity of the select line structure SLS and to improve operating characteristics of a select transistor. During an erase operation, it is possible to generate a sufficient amount of GIDL current.

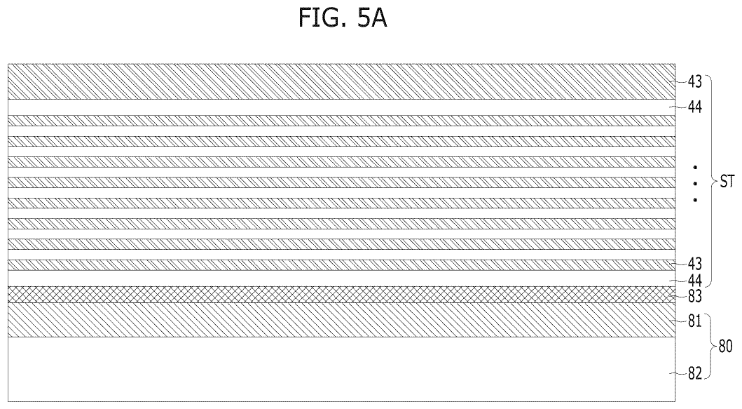

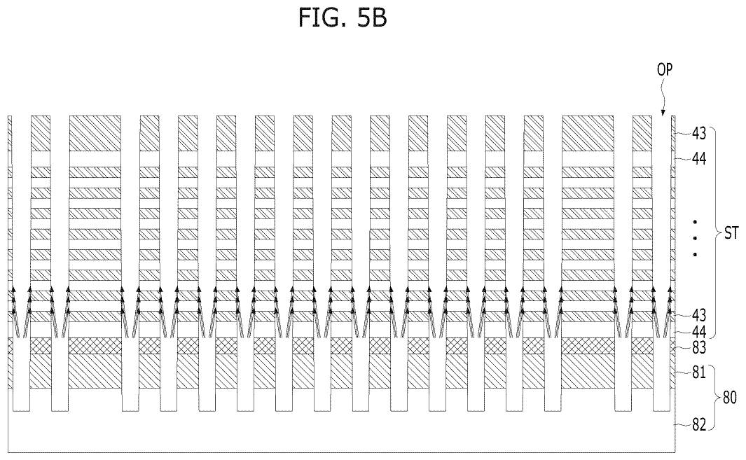

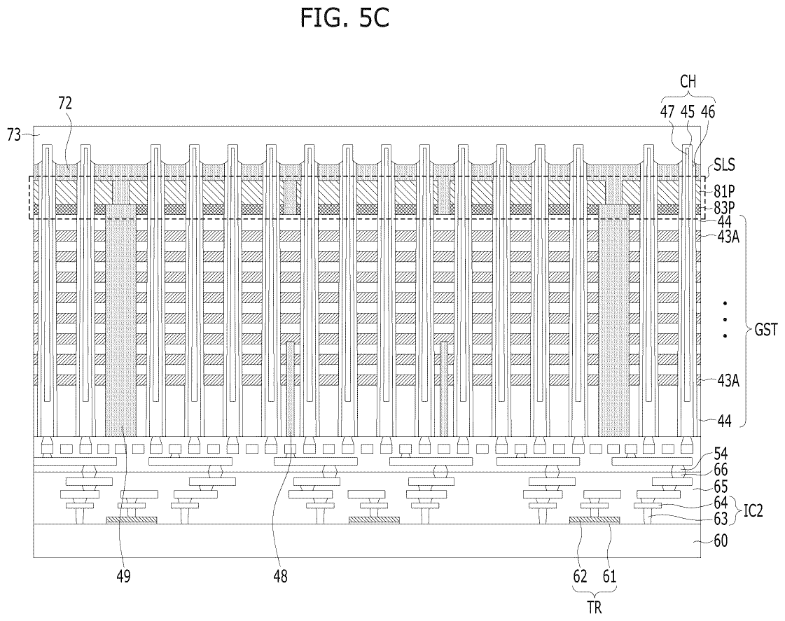

FIGS. 5A to 5C are diagrams for describing a manufacturing method of a semiconductor device in accordance with an embodiment. Hereinafter, the content overlapping with the previously described content will be omitted.

Referring to FIG. 5A, a first substrate 80 may include an epitaxial layer 81 on a front surface thereof. The first substrate 80 may include a bulk 82 and the epitaxial layer 81. A silicide layer 83 may be formed on the first substrate 80. The silicide layer 83 may be formed by siliciding the epitaxial layer 81. As an example, after a metal layer is formed on the epitaxial layer 81, the metal layer and the epitaxial layer 81 may be reacted through a heat treatment process. The metal layer may include a material capable of generating a photocatalyst in a subsequent process, and may include, for example, titanium (Ti). Subsequently, an unreacted metal layer may be removed and a cleaning process may be performed. Through this, a surface of the epitaxial layer 81 may be silicided.

Subsequently, a stack ST may be formed on the silicide layer 83. The stack ST may include first material layers 43 and second material layers 44 that are alternately stacked.

Referring to FIG. 5B, an opening OP may be formed in the stack ST. The opening OP may extend into the first substrate 80 through the stack ST, the silicide layer 83, and the epitaxial layer 81. The opening OP may extend into the bulk 82. The opening OP may be used to form a channel structure, a contact plug, a slit structure, or the like.

As an example, a mask pattern may be formed on the stack ST, and the stack ST may be etched using the mask pattern as an etching barrier. The opening OP may have a shape with a high aspect ratio. Due to characteristics of an etching process, a lower width of the opening OP may be smaller than an upper width thereof. By-products generated during the etching process may be deposited on an inner wall of the opening OP, and the lower width of the opening OP may be reduced due to the deposited by-products. Accordingly, the by-products deposited on the inner wall of the opening OP may be removed using a photocatalyst. An etchant used in an etching process for forming the opening OP may react with the silicide layer 83, and a photocatalyst formed by the reaction may activate decomposition of ions and/or radicals. Through this, the lower width of the opening OP may be increased. The silicide layer 83 may include a titanium silicide layer (TiSix), and titanium oxide (TiO₂) generated from the silicide layer 83 may act as a photocatalyst to remove polymer on the inner wall.

Referring to FIG. 5C, a channel structure CH may be formed in the opening OP. Subsequently, a first isolation structure 48, a gate structure GST, a slit structure 49, a first interconnection structure IC1, a first interlayer dielectric layer 53, and a first bonding pad 54 may be formed. Subsequently, a second wafer WF2 including a peripheral circuit PC and a first wafer WF1 may be bonded to each other.

Subsequently, the epitaxial layer 81 may be exposed by removing a rear surface of the first substrate 80. Subsequently, the epitaxial layer 81 and the silicide layer 83 may be etched to form epitaxial patterns 81P and silicide patterns 83P. Through this, a select line structure SLS including select lines may be formed.

Subsequently, a second isolation structure 72 may be formed. The second isolation structure 72 may be located on the epitaxial patterns 81P, and may extend between the epitaxial patterns 81P and between the silicide patterns 83P. Subsequently, a memory layer 46 of the channel structure CH protruding from the second isolation structure 72 may be etched to expose the channel layer 45, and a source structure 73 may be formed.

According to the manufacturing method described above, the silicide layer 83 may be formed between the epitaxial layer 81 and the stack ST. By using the silicide layer 83 as a photocatalyst source, it is possible to prevent or reduce a decrease in the lower width of the opening OP. Accordingly, it is possible to improve the width uniformity of a structure having a high aspect ratio such as the channel structure CH.

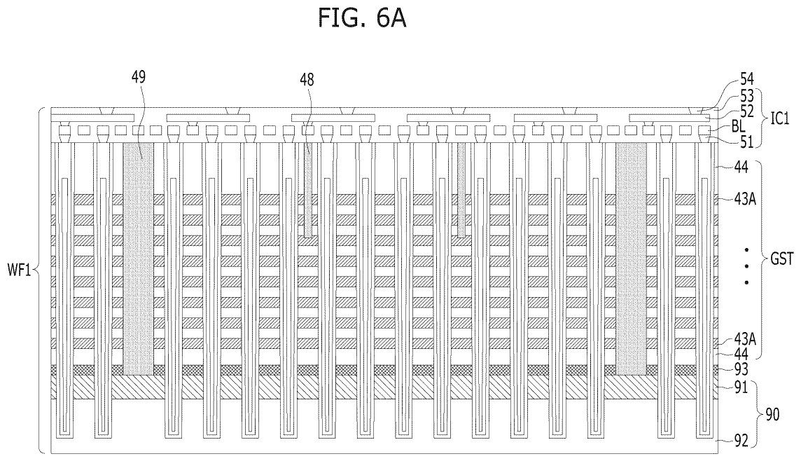

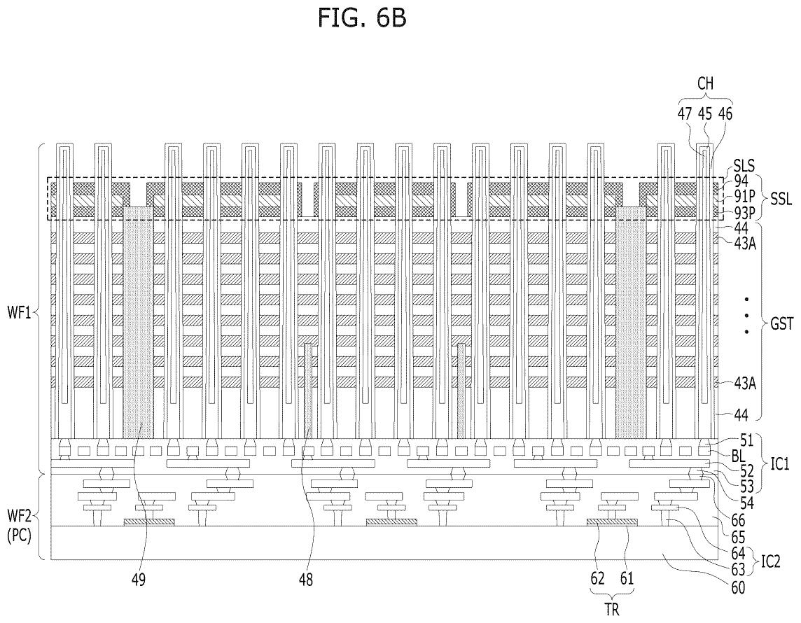

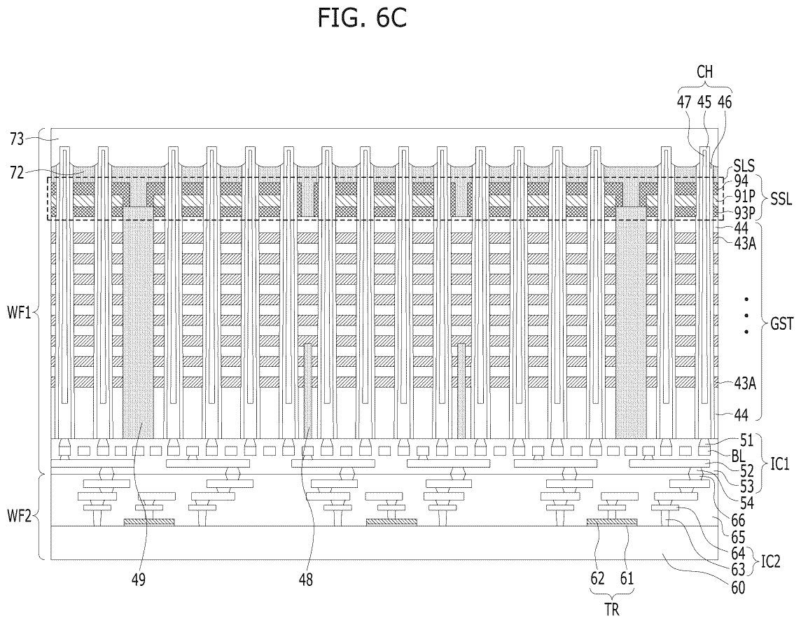

FIGS. 6A to 6C are diagrams for describing a manufacturing method of a semiconductor device in accordance with an embodiment. Hereinafter, the content overlapping with the previously described content will be omitted.

Referring to FIG. 6A, a first substrate 90 may include an epitaxial layer 91 on a front surface thereof. The first substrate 90 may include a bulk 92 and the epitaxial layer 91. A first silicide layer 93 may be formed on the first substrate 90. The first silicide layer 93 may be formed by siliciding the epitaxial layer 91. The first silicide layer 93 may include a material capable of generating a photocatalyst in a subsequent process, and may include a metal such as titanium (Ti). Subsequently, a stack ST may be formed on the first silicide layer 93. The stack ST may include first material layers 43 and second material layers 44 that are alternately stacked.

Subsequently, a channel structure CH may be formed. When the channel structure CH is formed, the uniformity of a width of an opening may be improved by a photocatalyst generated by the first silicide layer 93. Accordingly, a difference in width according to the level of the channel structure CH may be reduced. Subsequently, a first isolation structure 48, a gate structure GST, a slit structure 49, a first interconnection structure IC1, a first interlayer dielectric layer 53, and a first bonding pad 54 may be formed.

Referring to FIG. 6B, a first wafer WF1 and a second wafer WF2 including a peripheral circuit PC may be bonded to each other. Subsequently, the epitaxial layer 91 may be exposed by removing a rear surface of the first substrate 90. The channel structure CH may protrude from the epitaxial layer 91.

Subsequently, the epitaxial layer 91 and the first silicide layer 93 may be etched to form an epitaxial pattern 91P and a first silicide pattern 93P. The epitaxial pattern 91P and the first silicide pattern 93P may be patterned in substantially the same shape. A sidewall of the epitaxial pattern 91P and a sidewall of the first silicide pattern 93P may be aligned.

Subsequently, second silicide layers 94 may be formed. The second silicide layers 94 may be formed by siliciding the epitaxial patterns 91P. The second silicide layers 94 may surround the epitaxial patterns 91P, respectively. The second silicide layers 94 may each include nickel silicide. Through this, a select line structure SLS including the epitaxial pattern 91P, the first silicide pattern 93P, and the second silicide layer 94 may be formed. The select line structure SLS may include a plurality of select lines, and each select line may include the epitaxial pattern 91P, the first silicide pattern 93P, and the second silicide layer 94. The epitaxial pattern 91P may be located between the first silicide pattern 93P and the second silicide layer 94.

Referring to FIG. 6C, a second separation structure 72 may be formed on the select line structure SLS. Subsequently, the channel layer 45 may be exposed and a source structure 73 may be formed.

According to the manufacturing method described above, by using the first silicide layer 93 as a photocatalyst source, it is possible to prevent or reduce a decrease in the lower width of an opening when the channel structure CH, the slit structure 49, and the like are formed. Accordingly, it is possible to improve the width uniformity of a structure having a high aspect ratio. It is also possible to reduce the resistivity of the select line structure SLS through the second silicide layer 94.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure located between a bit line and a source structure, the gate structure including stacked word lines;
a select line structure located between the gate structure and the source structure, the select line structure including an epitaxial pattern and a silicide layer; and
a channel structure extending through the gate structure and the select line structure, the channel structure connected between the source structure and the bit line.

2. The semiconductor device of claim 1, wherein the silicide layer surrounds an upper surface and sidewalls of the epitaxial pattern.

3. The semiconductor device of claim 2, wherein the silicide layer includes nickel silicide.

4. The semiconductor device of claim 1, wherein the silicide layer is located under the epitaxial pattern.

5. The semiconductor device of claim 4, wherein the silicide layer includes titanium silicide.

6. The semiconductor device of claim 1, wherein the select line structure comprises:
a titanium silicide layer;
the epitaxial pattern located on the titanium silicide layer; and
a nickel silicide layer located on the epitaxial pattern.

7. The semiconductor device of claim 1, wherein the epitaxial pattern includes an undoped first epitaxial pattern and a doped second epitaxial pattern.

8. The semiconductor device of claim 7, wherein the doped second epitaxial pattern includes at least one of phosphorus (P) and boron (B).

9. The semiconductor device of claim 1, wherein the select line structure includes source select lines and the gate structure includes drain select lines.

10. The semiconductor device of claim 9, further comprising:
an isolation structure located between the select line structure and the source structure, the isolation structure extending between the source select lines.

11. The semiconductor device of claim 9, further comprising:
a first isolation structure located in the gate structure and extending between the drain select lines.

12. The semiconductor device of claim 11, further comprising:
a second isolation structure located between the select line structure and the source structure, extending between the source select lines, and located to face the first isolation structure with the word lines interposed therebetween.

13. The semiconductor device of claim 1, further comprising:
a slit structure extending into the select line structure through the gate structure.

14. The semiconductor device of claim 13, further comprising:
an isolation structure located between the select line structure and the source structure, the isolation structure extending into the select line structure to be connected to the slit structure.

15. The semiconductor device of claim 1, further comprising:
a peripheral circuit;
a bonding structure bonding the peripheral circuit to a cell array, wherein the cell array includes the gate structure, the select line structure, and the channel structure.

16. A semiconductor device comprising:
a cell array including a gate structure including drain select lines and word lines, source select lines each including an epitaxial pattern and a silicide layer;
a first bonding pad electrically connected to the cell array;
a peripheral circuit; and
a second bonding pad electrically connected to the peripheral circuit and the first bonding pad.

17. The semiconductor device of claim 16, wherein the silicide layer surrounds an upper surface and sidewalls of the epitaxial pattern, and wherein the silicide layer includes nickel silicide.

18. The semiconductor device of claim 16, wherein the silicide layer is located under the epitaxial pattern, and wherein the silicide layer includes titanium silicide.

19. The semiconductor device of claim 16, wherein each of the source select lines comprises:
a titanium silicide layer;
a nickel silicide layer; and
the epitaxial pattern located between the titanium silicide layer and the nickel silicide layer.
